(19) United States
(12) Patent Application Publication
(10) Pub. No.: US 2008/0316064 A1
(43) Pub. Date: Dec. 25, 2008

(54) Keypad structure and electronic device using the same

(75) Inventor: Xiao-Long Wang, Suzhou (CN)

Correspondence Address: BACON & THOMAS, PLLC, 625 SLATERS LANE, FOURTH FLOOR, ALEXANDRIA, VA, 22314-1176, US

(73) Assignee: Qisda Corporation, Taoyuan Shien (TW)

(21) Appl. No.: 12/155,593

(22) Filed: Jun. 6, 2008

(30) Foreign Application Priority Data
Jun. 25, 2007 (TW) 96122965

(51) Int. Cl. H03M 11/00

(52) U.S. Cl. 341/22

(57) ABSTRACT

A keypad structure and an electronic device using the same are provided. The electronic device comprises at least a keypad structure and a printed circuit board. The keypad structure comprises a switch, a keypad body, and a touching element. The keypad body having a through hole is relatively disposed to the switch. The touching element is inserted into the through hole. There is a touching distance defined between the touching element and the switch, and the touching element can be moved relatively to the keypad body for adjusting the touching distance. Also, the printed circuit board is electrically connected to the switch.

This application claims the benefit of Taiwan application Serial No. 096122965, filed Jun. 25, 2007, the subject matter of which is incorporated herein by reference.

### BACKGROUND OF THE INVENTION

1. Field of the Invention

The invention relates in general to a keypad structure and an electronic device using the same, and more particularly to the keypad structure and the electronic device using the same capable of adjusting sense of touch and press.

2. Description of the Related Art

In the modern time, a variety of the electronic devices is part of the human's daily life and the functions of the electronic device are more complex. Nowadays, electronic products such as mobile phone, MP3 and game machine etc, are so common that almost everybody has at least one in their pockets or handbags, needless to say the number of electronic products used at home. Since the demand and the use of electronic products are on the rise, technology groups are actively developing various functions for electronic products to meet market needs and also to upgrade the level of products. All functions of electronic product are entered through an input device, and the most popular way to enter the functions is using the keypads.

FIG. 1 is a cross-sectional view of a conventional keypad structure. The conventional keypad structure 10 includes a keypad 12, an elastic plate 14, a switch 16 and a printed circuit board 18. When the keypad 12 is pressed by an external force, the switch 16 is triggered by the touch of the elastic plate 14, and the printed circuit board 18 is triggered by the switch 16 so as to output a signal. However, after a long operation time, material fatigue of the elastic plate 14 would be occurs due to a thousand times of pressing the keypad 12. When material fatigue of the elastic plate 14 occurs, the sensitivity of the keypad structure 10 is decreased, and the keypad structure 10 can't instantly give the user wanted response. Furthermore, if the sense of touch and press of the keypad 12 is needed to be adjusted, or material fatigue of the elastic plate 14 occurs, it is inconvenient and time-consuming that the whole conventional keypad structure 10 needs to be taken apart for replacing the components inside the structure 10.

### SUMMARY OF THE INVENTION

The invention is directed to a keypad structure and an electronic device using the same. The keypad structure and the electronic device using the same are capable of adjusting the touch distance between the touching element and the switch, such that the user could adjust the sense of touch and press according to personal favor.

According to a first aspect of the present invention, a keypad structure is provided. The keypad structure comprises a switch, a keypad body and a touching element. The keypad body having a through hole is relatively disposed to the switch. The touching element is inserted into the through hole. A touching distance is defined between the touching element and the switch, wherein the touching element can be moved relatively to the keypad body for adjusting the touching distance.

According to a second aspect of the present invention, an electronic device is provided. The electronic device comprises at least one keypad structure and a circuit board. The keypad structure comprises a switch, a keypad body and a touching element. The keypad body having a through hole is relatively disposed to the switch. The touching element is inserted into the through hole. A touching distance is defined between the touching element and the switch, wherein the touching element can be moved relatively to the keypad body for adjusting the touching distance. The printed circuit board is electrically connected to the switch.

The invention will become apparent from the following detailed description of the preferred but non-limiting embodiments. The following description is made with reference to the accompanying drawings.

### BRIEF DESCRIPTION OF THE DRAWINGS

FIG. 1 is a cross-sectional view of a conventional keypad structure.

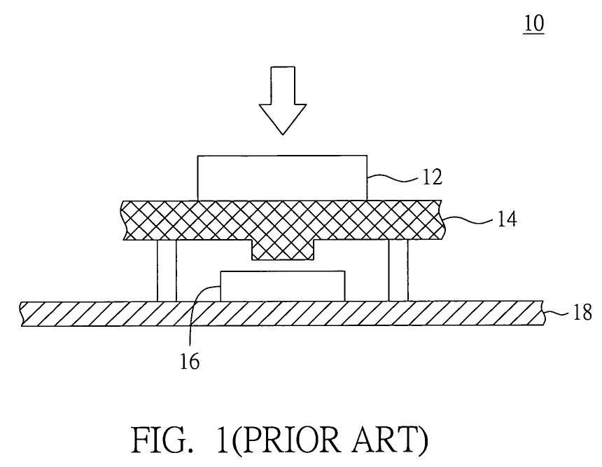

FIG. 2 schematically shows an electronic device with a keypad structure according to a preferred embodiment of the present invention.

FIG. 3A schematically shows a keypad structure according to a preferred embodiment of the present invention.

FIG. 3B shows a cross-sectional view along the cross-sectional line 3B-3B′ of the keypad structure in FIG. 3A.

FIG. 3C is a disassemble drawing of the keypad structure in FIG. 3A.

FIG. 4 is a diagram of another touching element according to a preferred embodiment of the invention.

### DETAILED DESCRIPTION OF THE INVENTION

In the present embodiment of the invention, a keypad structure and an electronic device using the same are provided for being capable of adjusting sense of touch and press. It is noted that the embodiment disclosed herein is used for illustrating the present invention, but not for limiting the scope of the present invention. Additionally, the drawings used for illustrating the embodiment and applications of the present invention only show the major characteristic parts in order to avoid obscuring the present invention. Accordingly, the specification and the drawings are to be regard as an illustrative sense rather than a restrictive sense.

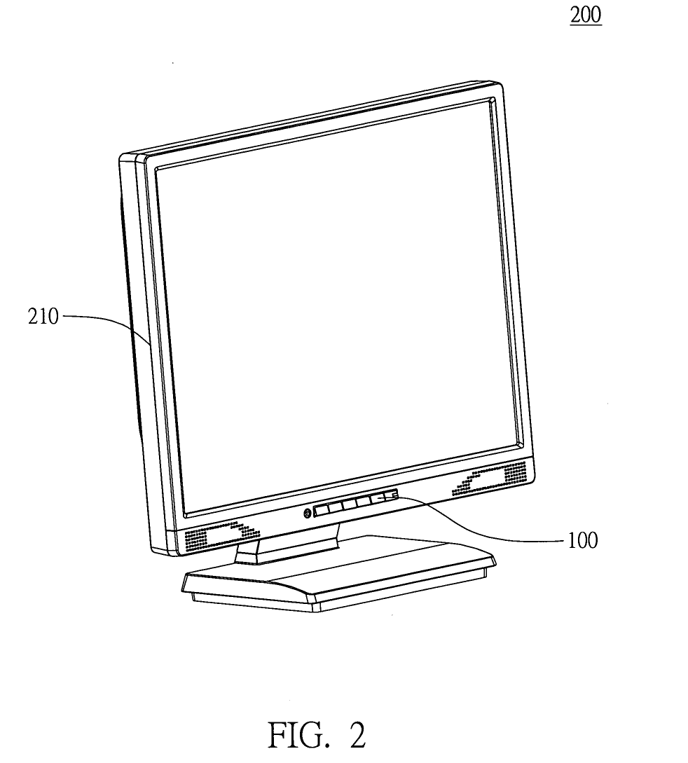

FIG. 2 schematically shows an electronic device with a keypad structure according to a preferred embodiment of the present invention. The electronic device 200 includes at least one keypad structure 100 is disposed on a display panel 210. In this embodiment, a display device is exemplified as the electronic device, but it is known to people skilled in the art that the keypad structure 100 could be applied to other electronic devices and not limited in the application of display device.

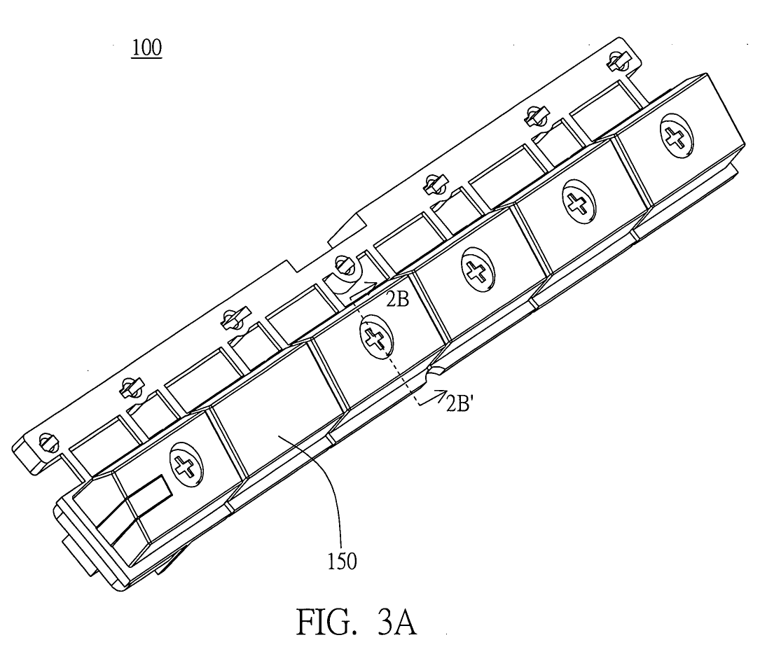

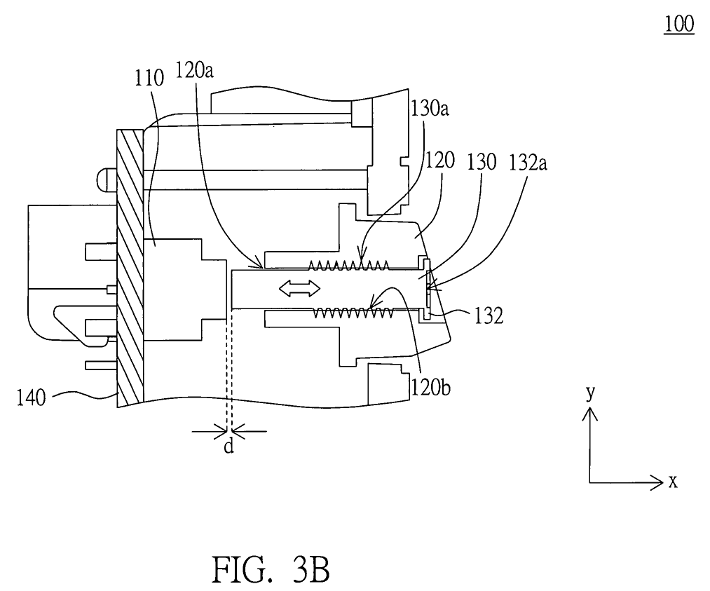

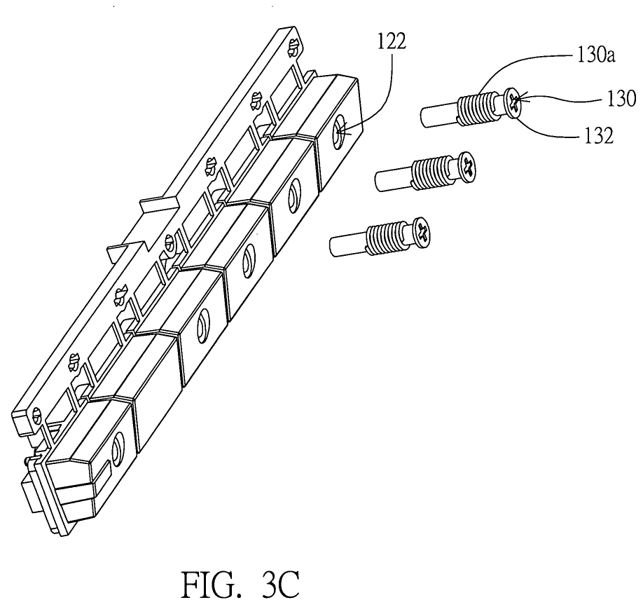

FIG. 3A schematically shows a keypad structure according to a preferred embodiment of the present invention. FIG. 3B shows a cross-sectional view along the cross-sectional line 3B-3B′ of the keypad structure in FIG. 3A. In practical application, the keypad structure 100 could be disposed on an electronic device 200 as shown in FIG. 2. Also, FIG. 3A only presents the keypad structure 100 and other components of the electronic device 200 are omitted for clear expression. As shown in FIG. 3B, the keypad structure 100 comprises a switch 110, a keypad body 120 and a touching element 130. The keypad body 120 having a through hole 120a and relatively disposed to the switch 110. The touching element 130 is inserted into the through hole 120a. There is a touching distance d between the switch 110 and the touching element 130. The touching element 130 can be moved relatively to the keypad body 120 for adjusting the touching distance d. Furthermore, the electronic device 200 further comprises a printed circuit board 140, and the circuit board 140 is electrically connected to the switch 110. When the switch 110 is pressed by the touching element 130 and the printed circuit board 140 is triggered by the switch 110, a keypad signal is outputted by the printed circuit board 140.

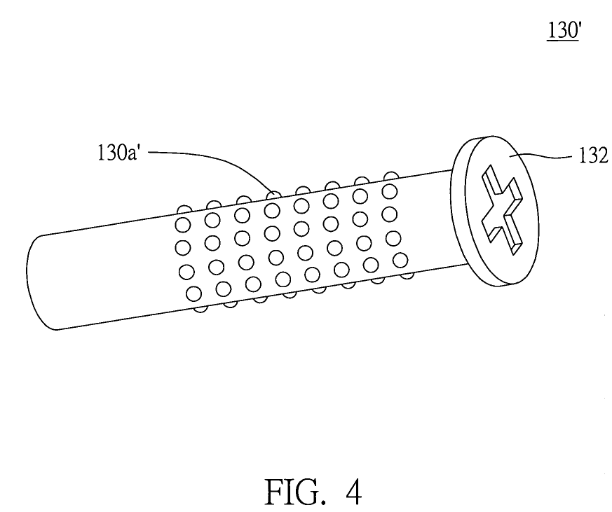

FIG. 3C is a disassemble drawing of the keypad structure in FIG. 3A. The keypad body 120 has a through hole 120a and the through hole 120a has a spiral inner wall 120b (as shown in FIG. 3B). The surface of the touching element 130, such as a spiral surface 130a (FIG. 3B, or alternatively the projections on the surface of the touching element 130 as shown in FIG. 4), is inserted into the through hole 120a. The spiral surface 130a of the touching element 130 is screwed with the spiral inner wall 120b of the through hole 120a, so that the touching element 130 can be moved relatively to the keypad body 120 by changing the relative positions between the touching element 130 and the through hole 120a.

Also, the touching element 130 comprises an adjusting portion 132. The adjusting portion 132 is positioned on the end of the touching element 130 for adjusting the touching element 130, such that the touching element 130 can be moved relatively to the keypad body 120, and the touching distance d between the touching element 130 and the keypad body 120 can be optionally changed. Practically, the touching distance d could be determined and adjusted according to user's feeling of touching keypad. In this embodiment, the width of the adjusting portion 132 is larger than the width of the through hole 120a for limiting the moving range of the touching element 130 relative to the keypad body 120. Since the moving range of the touching element 130 is limited, the touching distance d is adjusted within a certain range and it can be avoided that the touching element 130 over-presses the switch 110.

However, it is not limited that the width of the adjusting portion 132 is larger than the width of the through hole 120a as shown in FIG. 3C. The width of the adjusting portion 132 could be smaller than or equal to the width of the through hole 120a. If the width of the adjusting portion 132 is smaller than the width of the through hole 120a, the moving range of the touching element 130 relative to the keypad body 120 is not limited. Thus, the width of the adjusting portion 132 can be designed according to the requirements of the practical applications.

Also, the adjusting portion 132 of the touching element 130 has a notch, such as a slot or a crisscross gap. In this embodiment, the notch 132a is exemplified as a crisscross gap. The touching element 130 is screwed in the through hole 120a by engaging a receiving tool (ex: Slotted Screwdriver or Philips Screwdriver) with the notch 132a, for moving the touching element 130 relatively to the keypad body 120.

Moreover, after the keypad body 120 is pressed, a recover force of the keypad body 120 can be generated through the connected frame, so that the keypad body 120 can be moved back towards the +x direction. Furthermore, an elastic component such as spring could be incorporate with (ex. mounted on) the keypad body 120 in another embodiment, wherein the elastic component is compressed or extended when the relative position between the touching element 130 and the keypad body 120 is adjusted.

In this embodiment, when the touching element 130 is moved relatively to the keypad body 120, the touching distance d between the touching element 130 and the switch 110 will be changed. If the touching element 130 is adjusted by moving towards the +x direction, the touching distance d becomes larger and the user has to apply more external force on the keypad structure 100 to against the larger touching distance d. Similarly, if the touching element 130 is adjusted by moving towards the −x direction, the touching distance d becomes smaller and the user could apply less external force on the keypad structure 100 to against the smaller touching distance d. However, every one has his personal favor on the sense of touching and pressing keypad. Some people may like to press the keypad structure 100 heavily, and others may like to press the keypad structure 100 lightly. Thus, the touching distance d between the touching element 130 and the switch 110 could be altered by changing the relative position between the touching element 130 and the keypad body 120. Therefore, the keypad structure 100 of the present invention is adjustable according to different users' favors on the sense of touch and pressing the keypads.

According to the description above, the touching element 130 can be moved relatively to the keypad body 120 so as to change the touching distance d. Thus, the touching distance d could also be shortened (by screwing the touching element 130) to solve the problem of material fatigue of the keypad structure 100. After appropriate adjustment, the keypad structure 100 could give the user almost original or favorite sense of touching and pressing without replacing the mechanical components of the keypad structure 100.

Additionally, the operating staff on the production line could also properly adjust the touching distance d in the factory to maintain every keypad of the structure 100 in the same or very similar sense of touch and press.

Please refer back to FIG. 3A. The keypad structure 100 further comprises a cover 150. For clear description, only one cover 150 is drawn in FIG. 3A. The cover 150 is disposed on the keypad body 120 to cover the touching element 130 for appearance beauty and protection.

FIG. 4 is a diagram of another touching element according to a preferred embodiment of the invention. The touching element 130 in FIG. 3A has spiral surface 130a, and the spiral surface 130a is threaded into the spiral inner wall 120b of the through hole 120a. Besides the spiral surface 130a, several projections 130a′ could be formed on the surface of the touching element, alternatively. As shown in FIG. 4, the touching element 130′ has several projections 130a′ on the surface. The touching element 130′ could be screwed into the spiral inner wall 120b by the surface with projections 130a′ for moving the touching element 130′ relatively to the keypad body 120. Although the keypad structure is demonstrated by two kinds of screw structures (i.e. spiral surface 130a or projections 130a′), it is understood that the screw structure is not limited to the two examples herein.

According to the-keypad structure and the electronic device using the same are disclosed in the above-mentioned embodiments of the present invention, the sense of touching and pressing the keypad could be adjusted optionally according to user's favors by adjusting the touching distance d between the touching element and the switch. Further, the material fatigue of each component of the keypad structure can be solved by adjusting the touching distance d. Moreover, the operating staff on the production line could also properly adjust the touching distance d to maintain the sense of touch and press on every keypad in the same or very similar condition.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A keypad structure, comprising:
a switch;
a keypad body, having a through hole and relatively disposed to the switch; and
a touching element, inserted into the through hole, and a touching distance being defined between the touching element and the switch, wherein the touching element can be moved relatively to the keypad body for adjusting the touching distance.

2. The keypad structure according to claim 1, wherein the through hole has a spiral inner wall.

3. The keypad structure according to claim 2, wherein the touching element has a spiral surface, and the spiral surface is screwed with the spiral inner wall of the through hole for moving the touching element relatively to the keypad body.

4. The keypad structure according to claim 2, wherein the touching element has a plurality of projections on the surface, and the surface with projections is screwed with the spiral inner wall of the through hole for moving the touching element relatively to the keypad body.

5. The keypad structure according to claim 1, wherein the touching element comprises:
an adjusting portion, positioned on one end of the touching element for adjusting the touching element such that the touching element is moved relative to the keypad body.

6. The keypad structure according to claim 5, wherein the adjusting portion has a notch capable of engaging a tool, and the touching element can be moved relatively to the keypad body by rotating the adjusting portion with the tool.

7. The keypad structure according to claim 5, wherein the width of the adjusting portion is smaller than or equal to the width of the through hole.

8. The keypad structure according to claim 5, wherein the width of the adjusting portion is larger than the width of the through hole, and the touching element is moved relatively to the keypad body within a certain moving range.

9. The keypad structure according to claim 1, further comprising: a cover, disposed on the keypad body for covering the touching element.

10. An electronic device, comprising:
at least one keypad structure, comprising
a switch;
a keypad body, having a through hole and relatively disposed to the switch; and
a touching element, inserted into the through hole, and a touching distance being defined between the touching element and the switch, wherein the touching element can be moved relatively to the keypad body for adjusting the touching distance; and
a circuit board, electrically connected to the switch.

11. The electronic device according to claim 10, wherein the through hole has a spiral inner wall.

12. The electronic device according to claim 11, wherein the touching element has a spiral surface, and the spiral surface is screwed with the spiral inner wall of the through hole for moving the touching element relatively to the keypad body.

13. The electronic device according to claim 11, wherein the touching element has a plurality of projections on the surface, and the surface with projections is screwed with the spiral inner wall of the through hole for moving the touching element relatively to the body.

14. The electronic device according to claim 10, wherein the touching element comprises:
an adjusting portion, positioned on one end of the touching element for adjusting the touching element such that the touching element is moved relative to the keypad body.

15. The electronic device according to claim 14, wherein the adjusting portion has a notch capable of engaging a tool, and the touching element can be moved relatively to the keypad body of the keypad by rotating the adjusting portion with the tool.

16. The electronic device according to claim 14, wherein the width of the adjusting portion is smaller than or equal to the width of the through hole.

17. The electronic device according to claim 14, wherein the width of the adjusting portion is larger than the width of the through hole, and the touching element is moved relatively to the keypad body within a certain moving range.

18. The electronic device according to claim 10, wherein the keypad structure further comprising:
a cover, disposed on the keypad body for covering the touching element.
